(19) United States
(12) Patent Application Publication
(10) Pub. No.: US 2013/0252052 A1
(43) Pub. Date: Sep. 26, 2013

(54) Integrated Busbar, Terminal Pin And Circuit Protection For Sensing Individual Battery Cell Voltage

(71) Applicant: Evan J. Dawley, Rochester Hills, MI (US)

(72) Inventor: Evan J. Dawley, Rochester Hills, MI (US)

(73) Assignee: GM GLOBAL TECHNOLOGY OPERATIONS LLC, Detroit, MI (US)

(21) Appl. No.: 13/425,683

(22) Filed: Mar. 21, 2012

(51) Int. Cl. H01M 10/48; H01M 2/00; H01M 10/04; H01M 2/10; H01M 2/30; G01R 31/36; H01M 2/02

(52) U.S. Cl. 429/93; 324/434; 29/623.1

(57) ABSTRACT

A battery pack, an integrated device for sensing individual battery voltage in a battery pack and a method of forming an integrated voltage-sensing circuit for use in a battery-powered automobile propulsion system. The integrated voltage-sensing circuit includes a busbar, a terminal pin and a voltage-sensing fuse electrically disposed between the busbar and the terminal pin. The construction of the voltage-sensing circuit is such that it forms an integral structure upon being coupled to the modular housing or related structure that may subsequently be secured to a frame that is used to provide support to each battery cell within the battery pack. In one form, the modular housing and voltage-sensing circuit may be secured to the frame during a frame molding process such that upon completion of the molding, the housing and at least a portion of the voltage-sensing circuit are encapsulated within the frame.

### BACKGROUND OF THE INVENTION

This invention relates generally to voltage-sensing components used in conjunction with a battery-powered system, and more particularly to a method of integrating separate voltage-sensing components into a unified battery assembly as a way to increase assembly robustness and manufacturability of battery cell voltage-sensing components.

The increasing demand to improve vehicular fuel economy and reduce vehicular emissions has led to the development of both hybrid vehicles and pure electric vehicles. Pure electric vehicles may be powered by a battery pack (also called a battery), while hybrid vehicles include two or more energy sources, such as a gasoline (also referred to as an internal combustion) engine used as either a backup to or in cooperation with a battery pack. There are two broad versions of hybrid vehicles currently in use. In a first version (known as a charge-depleting hybrid architecture), the battery can be charged off a conventional electrical grid such as a 120 VAC or 240 VAC power line. In a second version (known as a charge-sustaining hybrid architecture), the battery receives all of its electrical charging from one or both of the internal combustion engine and regenerative braking. In either version, the battery pack is typically made from numerous modules, which in turn are made up of numerous individual cells. Numerous frames, trays, covers and related structure may be included to provide support for the various cells, modules and packs, and as such help to define a larger assembly of such cells, modules or packs.

In one form, the cells of the battery pack delivers direct current (DC) electricity; this current may in turn be used to provide power to various vehicle systems, such as motors, electric traction systems (ETS) or the like, as well as ancillary equipment. A power inverter is typically employed for components that need alternating current (AC) rather than DC power; these power inverters typically include capacitor modules and an integrated gate bipolar transistor (IGBT) for converting the DC input signal to an AC output signal. In a common form, these modules are connected via busbar or cabling assemblies. The busbars interact electrically with the various cells of the battery pack through thin metal tabs that project out of an edge of the generally planar cells of the pack. Both the bus bars and the tabs are typically made of copper, aluminum or alloys thereof. In some cases, the tabs or related conductors may be coated with a thin layer of other metal to enhance corrosion resistance or other desirable properties.

The busbar is generally seen to be advantageous over cabling assemblies because (among other things) it—in addition to providing electrical connectivity—makes it possible to integrate voltage-sensing and monitoring electronics with the power connection. Furthermore, its general structure allows all of the tabs used to provide electrical connection among the individual cells to be reliably and repeatably positioned relative to one another through a simple assembly operation. In one form, the monitoring (such as cell voltage-sensing through the circuit-protection fuses) is typically accomplished using a circuit protection device (i.e., a fuse) as an electrical interface between the busbar and a terminal pin that is formed as part of the aforementioned frame that is used to provide structural support of the battery cell or cells.

Despite these advantages, conventional busbars suffer from certain drawbacks. These shortcomings are particularly acute when trying to connect the circuit-protection fuses to the frame after the frame has already been molded or otherwise formed. First, in one common assembly approach, the busbar must be snap-fit or heat staked to the frame. The snap fit in particular is not a robust process and allows for too much variation. Second, resistance welding the small leads of the fuse to both the busbar and the terminal pin requires fine alignment and process windows, which are difficult to meet when incorporated into a larger part. Third, the fuse leads themselves may be exposed to mechanical loads; generally, the small leads of the fuse are not robust enough to function as both a mechanical and electrical link between the terminal and busbar. Thus, any errors or reduction in weld quality will influence throughput as the fuse leads eventually fatigue and fail. Likewise, these assembly difficulties result in a significant probability of failure and related production reject rate, thereby driving up production costs.

### SUMMARY OF THE INVENTION

In accordance with the teachings of the present invention, a method of forming an integrated circuit for use in a battery-powered automobile propulsion system is disclosed. The circuit includes a fuse with leads for establishing electrical communication between a busbar and a terminal pin. In a preferred form, there is a circuit for each cell within a larger battery pack or related assembly. In the present context, the circuit may be formed as part of a connector housing (also referred to herein more simply as housing) that in turn is permanently secured to or otherwise formed as part of the frame; in either event, the integral nature of the connection between the frame and the voltage-sensing circuit is such that being rigidly secured to one another, they are integral in functional sense, even if some visible indicia of their original separate nature may remain. As such, by being integrated into the frame within the present context, the voltage-sensing circuit becomes a structural whole, thereby exhibiting the enhanced structural robustness vis-à-vis the approach of the prior art, where separately-formed voltage-sensing circuits that are more vulnerable to repeated handling and related breakage-prone events are likely to occur. In particular, the combination of the busbar, fuse and terminal pin that make up the integrated voltage-sensing circuit are—once coupled to the housing—configured as a modular whole with and within the housing such that together the housing and the circuit define an autonomous part that is a structurally-robust integrated structure within itself, as well as when it is secured to the larger frame (such as by overmolding, encapsulation or the like) to become an integral part thereof.

In accordance with another aspect of the present invention, an assembly for sensing voltage produced by a battery cell within a battery pack made up of a plurality of battery cells is disclosed. As mentioned above, the assembled circuit provides the means to measure the voltage of each individual cell in a battery pack. The voltage-sensing circuit is made up of at least three components, including a terminal pin, cladded busbar and fuse (i.e. circuit protection) that are assembled together to fit in a modular housing that in turn may be secured to a battery frame. By integrating these electrically-conductive pieces within a housing and further integrating this housing into a frame (for example, an injection-molded frame), a greater robustness of all components can be realized. This is especially valuable for the fuse that links the terminal pin and busbar, as being part of a compact, modular housing that can withstand far more harsh handling treatment than can the fuse and related components individually.

In accordance with yet another aspect of the present invention, a battery pack configured to provide propulsive power to a vehicle is disclosed. The battery pack includes numerous battery cells, a frame for each battery cell to allow the cell to be secured and a voltage-sensing circuit secured to the frame, where the voltage-sensing circuit includes the aforementioned fuse, busbar and terminal pin, as well as a housing configured to maintain the fuse, the busbar and the terminal pin in electrical communication with one another. In one particular form, the housing defines a molded structure such that once the connection between the various electrically-conductive components are made, the voltage-sensing circuit defines a modular unit. As mentioned above, the molded structure of the housing is preferably further molded into the molded structure of frame; such molding, encapsulation, overmolding or the like ensures an integral connection between the housing and frame. In a preferred form, the shapes defined by the molded housing include various formations for receiving the electrically-conductive parts of the voltage-sensing circuit. It will be appreciated by those skilled in the art that the battery pack may include additional features for mechanical or electrical support, including additional frames, containers, cooling circuits or the like.

### BRIEF DESCRIPTION OF THE DRAWINGS

The following detailed description of specific embodiments can be best understood when read in conjunction with the following drawings, where like structure is indicated with like reference numerals and in which:

FIG. 1 is a schematic diagram of an exemplary vehicle configured with a hybrid power source, showing the integration of a battery pack with and various other subcomponents of the vehicle;

FIGS. 2A and 2B show respective top and elevation views of the connection between a busbar, terminal pin and fuse of a voltage-sensing circuit according to the prior art;

FIG. 3A shows the molded housing with the terminal pin placed therein according to an aspect of the present invention;

FIG. 3B shows the housing of FIG. 3A connected to the busbar and fuse to define a modular, integral voltage-sensing circuit according to an aspect of the present invention;

FIG. 4A shows the busbar of FIG. 3B in isolation;

FIG. 4B shows the terminal pin of FIGS. 3A and 3B in isolation;

FIG. 5A shows a view from one side of the integration of the modular, integral voltage-sensing circuit of FIG. 3B into a portion of a battery cell frame; and

FIG. 5B shows a view from the opposing side of the integrated voltage-sensing circuit of FIG. 5A.

### DETAILED DESCRIPTION OF THE PREFERRED EMBODIMENTS

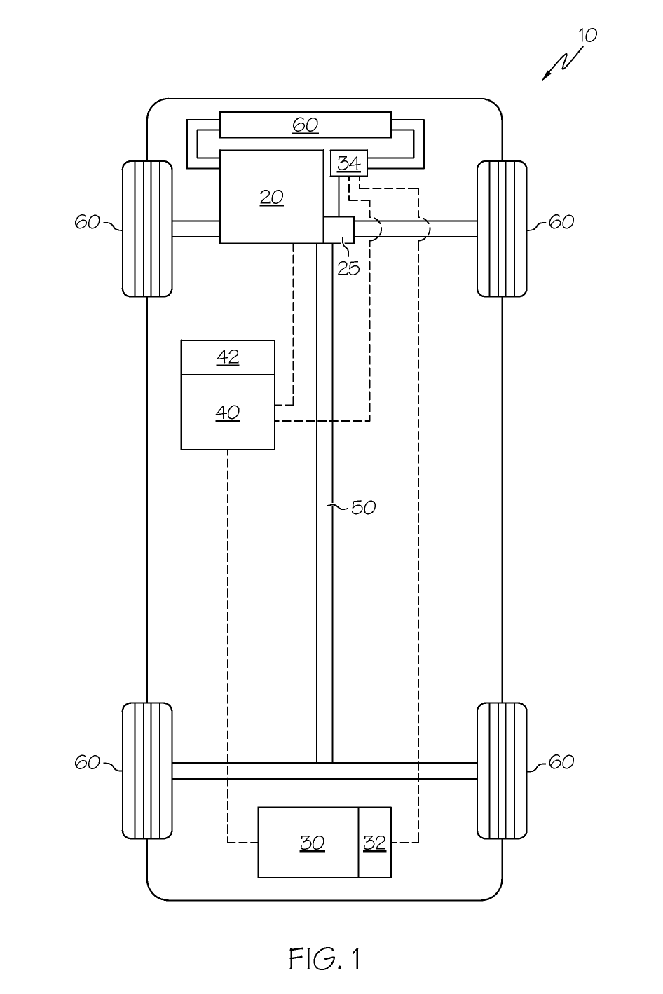

Referring first to FIG. 1, a schematic diagram of a hybrid-powered vehicle 10 in accordance with the present invention is shown. Within the present context, it will be appreciated that the term “vehicle” may apply to car, truck, van sport utility vehicle (SUV) or the like. Vehicle 10 includes an ICE 20, battery 30 and an electronic control system 40, where one or both of ICE 20 and battery 30 may be coupled to an electric motor/generator 25. Vehicle 10 further includes a powertrain 50 (which could be in the form of a driveshaft or the like) to deliver propulsive power from the ICE 20, motor/generator 25 or battery 30 to one or more of the wheels 60. Battery 30 includes a state of charge (SOC) system 32 and power inverter assembly 34, the latter of which includes various modules, including those for the IGBT and capacitors (not shown) as well as other conductive elements configured to provide a pathway for current flow between these and other associated battery-related electronic components. Busbar assemblies (portions of which are shown and discussed in more detail below) provide compact, reliable electrical connection between these various modules. Additional support equipment, such as radiator 60, is also shown. Although the battery 30 (which as discussed above may be placed in a frame as part of a larger assembly) is shown in the rear of vehicle 10, it may be located in any suitable location to facilitate its electrical coupling (via busbars discussed in more detail below) to the various electrical components. In one embodiment, battery 30 is an assembly or pack made up of numerous lithium ion (Li-ion) cells (not individually shown). The electronic control system 40 may include a variable motor drive module 42 to control electric motor torque and speed, as well as other vehicular functions. It will be appreciated by those skilled in the art that while vehicle 10 is presently shown as a hybrid-powered vehicle, that one with purely electric power (i.e., one with no need for ICE 20) is also deemed to be within the scope of the present invention.

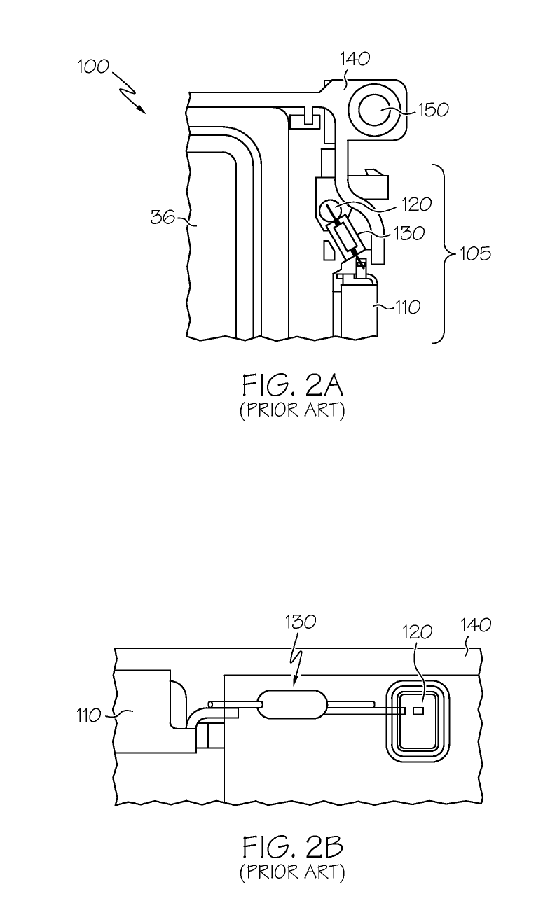

Referring next to FIGS. 2A and 2B, details depicting a portion of a notional prior art busbar subassembly 100 (FIG. 2A) and voltage-sensing circuit 105 made up of the connection between a busbar 110 and terminal pin 120 through a fuse 130 is shown. In particular, the various components making up the voltage-sensing circuit 105 are directly attached to a portion of frame 140 that is used to provide mechanical or structural support for these and other components. Furthermore, additional components, such as battery cell-supporting tray 36, are preferably sized to structurally cooperate with frame 140. In one form, the frame 140 is about ten inches (i.e., about 250 millimeters) in length along its longest edge and further includes apertures 150 formed therein to promote connection through a bolt or related fastener (not shown). It will be appreciated by those skilled in the art that only a small part of frame 140 is shown, where numerous such frames 140 (with mounted cells 36 and voltage-sensing circuits 105) are stacked or otherwise arranged to provide a mechanically rigid pathway to facilitate the flow of current from the individual battery cells 36 to the various power-consuming components in vehicle 10. Depending on the configuration, other components (not shown) of each individual busbar subassembly 100 may include a positive DC terminal, a negative DC terminal and an AC terminal, as well as numerous other components to establish electrical connectivity between the positive and negative terminals of the individual battery cells, as well as to other components of battery 30. Each busbar subassembly 100 transfers current received from the positive and negative terminals of the DC source (i.e., battery cell 36) to (among other components) IGBT devices, power diodes or other components that can either convert the DC signal to a single-phase AC signal. As mentioned above, in one form, at least the electrically-conductive portions of busbar subassembly 100 may be made from copper or a copper alloy, and may additionally be plated.

Upon stacking and connecting the various individual frames 140, a structural assembly resembling a substantially complete battery pack (such as battery 30) is formed. As mentioned above, each battery cell within battery 30 is mounted to a corresponding frame 140 that includes a mounting location where fuse 130 may be secured to the busbar 110 and terminal pin 120. In one particular form, a chassis or related larger container (not shown) may also be used to provide enclosure and related environmental protection for not only the battery 30, but also the internal electronic components, such as those that make up the power inverter assembly 34; such an additional container may be made from a suitable material with conductive features that can be grounded to the chassis of vehicle 10 to provide a ground source for housed electrical components.

The above approach to battery 30 construction necessitates that each voltage-sensing circuit 105 in general—and each fuse 130 in particular—be picked and placed onto the frame 140; furthermore the electrical leads (which are typically very small—for example—0.6 millimeter in diameter) of fuse 130 need to be aligned with the terminal pin 120 and busbar 110 for proper resistance welding. The manipulation of objects with disparate scales (specifically, the large scale of frame 140 and the much smaller scale of fuse 130) increases complexity of the assembling process, as movements deemed fine-motor within the larger scale may be far too coarse for the particular needs of the fuse 130 and its fragile leads. This in turn leads to potential handling or process-related damage to the voltage-sensing circuit 105.

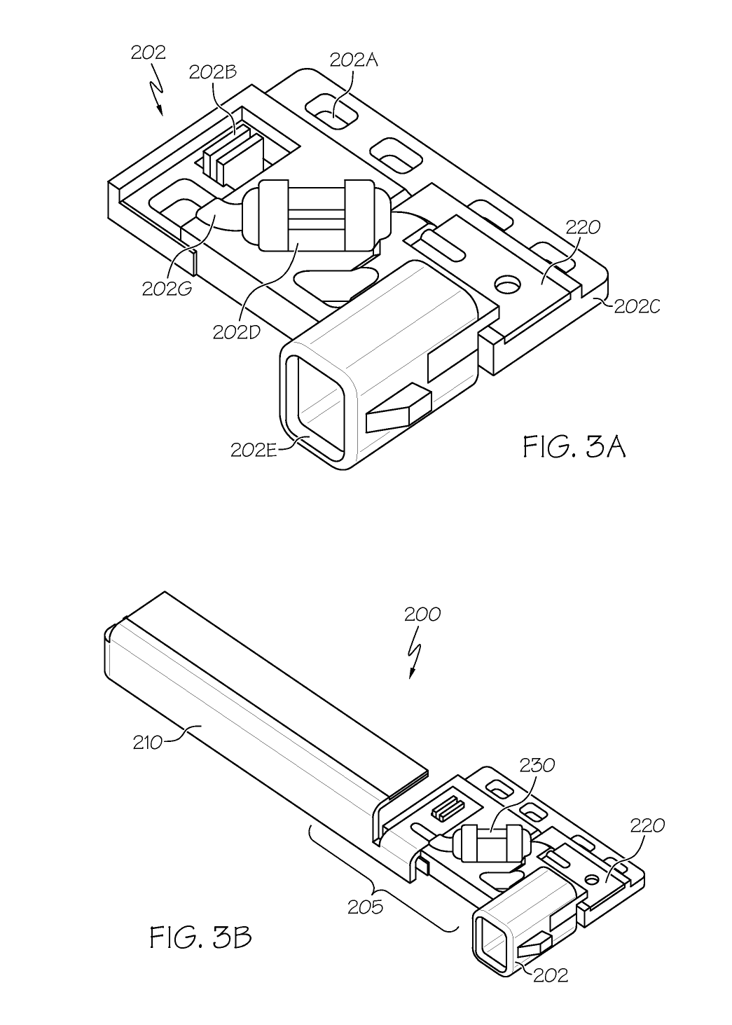

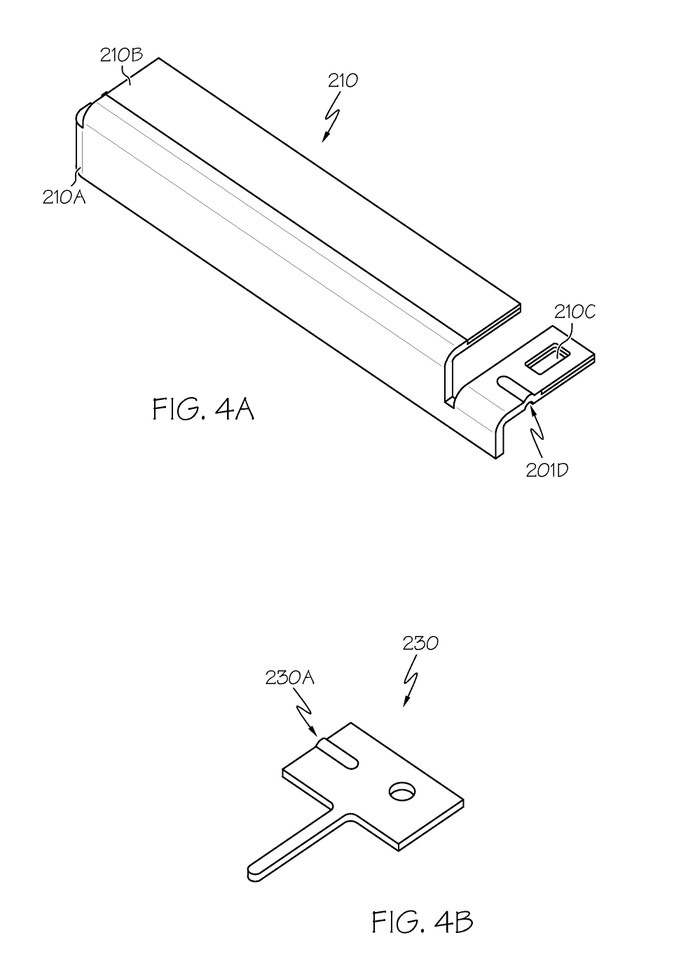

Referring next to FIGS. 3A, 3B, 4A and 4B, the various components making up a voltage-sensing circuit subassembly 200 (also referred to herein as assembly) according to an aspect of the present invention are shown. Referring first to FIGS. 3A and 3B, the subassembly 200 includes a housing 202 for containing the voltage-sensing circuit 205 as a way to reduce complexity, process variability and cost by having at least the busbar 210 and terminal pin 220 be integrally-formed within the housing 202 that will in turn be integrally formed (such as by overmolding or encapsulation) with a frame (such as frame 240) such that placement and alignment of fuse 230 is achieved with a significant reduction in the risk of damage. Various formations are defined in housing 202, including apertures 202A that permit liquid forms of molded frame material (for example, polypropylene) to pass through such that upon solidification, form a permanent, integral connection between the frame and housing 202. Other formations, such as 202B, 202C and 202D are used to define spaces where the busbar 210, terminal pin 220 and fuse 230, respectively may be mounted or otherwise placed. Likewise, connector 202E may be used to define a mounting location for other equipment that makes up, or is otherwise connected to, the frame. Formation 202G defines a bent path (shown notionally as being roughly serpentine) to allow the leads from fuse 210 to be attached to complementary surfaces on the busbar 210 and terminal pin 220. FIG. 3B shows with particularity how the housing 202 and the entirety of the busbar 210 form the voltage-sensing circuit subassembly 200. In one form of construction, the terminal pin 220 is placed in a mold—which may be a pre-defined slot or related shape formed in the housing 202, while the busbar 210 may be joined to the housing through appropriate connection. In any event, once the busbar subassembly 200 is formed, the fuse 230 may be inserted into the cavity or related indentation corresponding to formation 202D. As mentioned above, the electrically-conductive nature of the busbar 210 and terminal pin 220 is such that when secured to corresponding electrically-conductive leads 234, 232 of fuse 230, they form an electrically-continuous circuit 205. In particular, shaped portions 201D and 230A formed in the busbar 210 and terminal pin 220 respectively are sized to promote secure connection between the small-diameter leads 234, 232 of fuse 230. In one form, the connection may be through appropriate mechanical means, such as snap-fit, heat staking or the like, while electrical connection may be accomplished through resistance welding or another joining method to establish the fuse joints discussed below.

Referring with particularity to FIGS. 4A and 4B, as with the busbar subassembly 100 of the prior art, busbar subassembly 200 includes (in addition to fuse 230 that functions as a circuit-protection mechanism) a busbar 210 and terminal pin 220. Referring with particularity to FIG. 4A, the busbar 210 includes a generally conductive face 210A made from a copper alloy secured to a backing 210B made from an aluminum alloy. Aperture 210C is sized to cooperate with the detent-shaped formation 202B of the housing 202 of FIG. 3A.

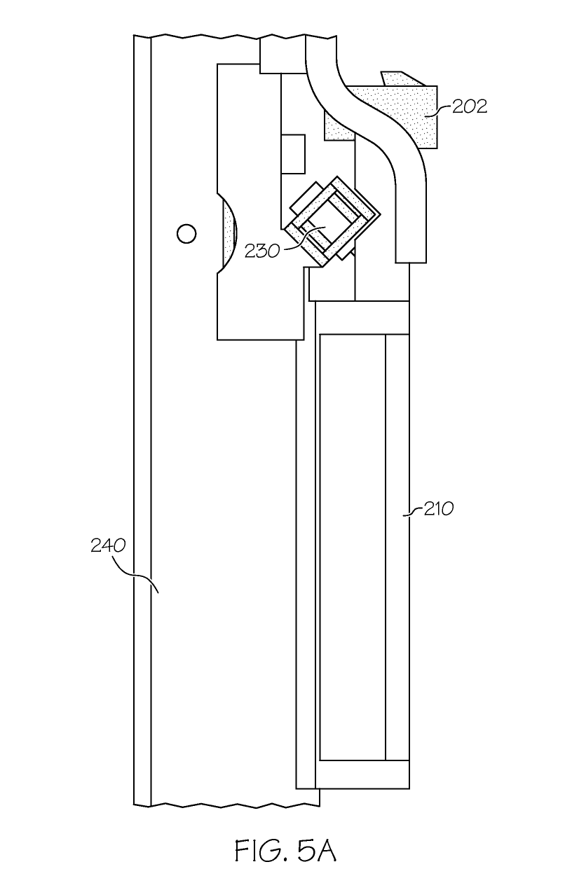

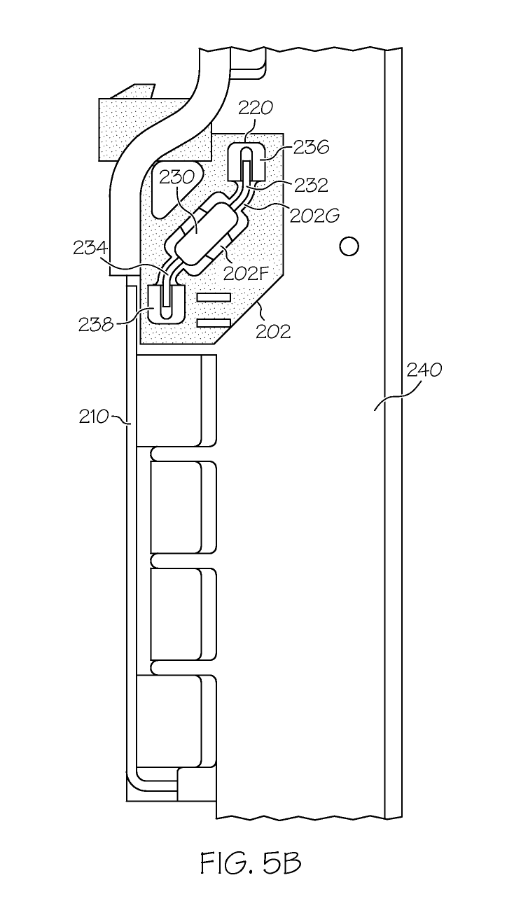

Referring next to FIGS. 5A and 5B, the integration of the frame 240 and the housing 202 is shown, where surface details are added to the latter to better emphasize initial lines of demarcation between the two structures. Unlike the prior art, the voltage-sensing circuit 205, by virtue of its integrated construction within housing 202, voltage-sensing circuit subassembly 200 and frame 240, has an increased resistance to environmental and mechanical loading, thus reducing the probability of a failure. The construction of the voltage-sensing circuit 205 is such that at least the locations within housing 202 where the fuse 230 and its leads 232, 234 are placed forms an integral structure that may subsequently be secured to frame 240. Thus in one form, the modular housing 202 and voltage-sensing circuit 205 may be secured to the frame 240 during a molding process of the frame 240 such that upon completion of the molding, the housing 202 and at least a portion of the voltage-sensing circuit 205 are encapsulated within the frame 240.

Referring with particularity to FIG. 5B, the fuse 230 (in general) and the fuse joints 236, 238 formed between the leads 232, 234 and their corresponding connection points on the respective terminal pin 220 and busbar 210 (in particular) are especially vulnerable to damage that can occur during normal fabrication and handling. Leads 232 and 234 extending from opposing ends of fuse 230 provide electrical connectivity to the terminal pin 220 and busbar 210, respectively, preferably through a resistance welding process. By having both properly-sized resilient connections and precision alignment between the leads 232 and 234, the fuse 230 may be secured to the housing 202 and the remainder of the busbar subassembly 200 with a higher degree of confidence that subsequent frame-handling (i.e., large-scale) operations will not exploit minute differences in small-scale misalignments within the fuse 230, busbar 210 and terminal pin 220 to jeopardize reliable fabrication of the voltage-sensing circuit 205. In a particular form, at least a significant portion of the busbar 210 and terminal pin 220 are encapsulated by the plastic of the frame 240 during the overmold process, while fuse 230 is preferably left substantially uncovered by the material of the frame 240. As can be seen in both of the present figures, there is significant coverage of the connection between the busbar 210 and the housing 202, as well as between the terminal pin 220 and the housing 202, while the fuse 230 and its leads 232, 234 remain substantially uncovered. The cavity or related indentation 202D (as best shown in FIG. 3A) in housing 202 has integrally-formed tabs or detents 202F to allow the fuse 230 to be securely snap-fit into place, while the serpentine walls 202G promote secure alignment of the leads 232, 234 to the respective contact surfaces of terminal pin 220 and busbar 210.

In one form, the fuse joints 236, 238 formed between the leads 232, 234 and their corresponding connection points on the respective terminal pin 220 and busbar 210 may be done through resistance welding. The tolerances that a smaller assembly (such as that which fits within or otherwise cooperates with housing 202) makes possible are a good fit with the dimensions of the fuse 230 and the demands of resistance welding. Furthermore, the compact, modular nature of housing 202 allows a fuse 230 secured thereto to be handled in a manner more consistent with the larger-scale structure of frame 240. Likewise, the present design of housing 202 is easily integrated within the host frame 240 by overmolding, thereby increasing structural continuity and related overall robustness and manufacturability.

By the present construction, the order of assembly of the present invention is the opposite of that of the prior art where the three electrically-connected components 110, 120 and 130 of the voltage-sensing circuit 105 are assembled after the molding or forming of the battery cell frame 140, whereas in the present invention, the components 210, 220 and 230 are combined in a single standalone unit before molding the battery cell frame 240. This enhances circuit 205 integrity by providing a built-in carrier in the form of housing 202 (at a first, more modular level) and the larger assembly 200 (at a second, slightly larger level). Furthermore, by using an overmolding process to secure the housing 202 or assembly 200 to the frame 240, at least the busbar 210, transfer pin 220 and their respective interconnects to the housing 202 are secured in place with a barrier to the ambient environment.

It is noted that terms like “preferably,” “commonly,” and “typically” are not utilized herein to limit the scope of the claimed invention or to imply that certain features are critical, essential, or even important to the structure or function of the claimed invention. Rather, these terms are merely intended to highlight alternative or additional features that may or may not be utilized in a particular embodiment of the present invention. Likewise, for the purposes of describing and defining the present invention it is noted that the term “substantially” is utilized herein to represent the inherent degree of uncertainty that may be attributed to any quantitative comparison, value, measurement, or other representation. The term is also utilized herein to represent the degree by which a quantitative representation may vary from a stated reference without resulting in a change in the basic function of the subject matter at issue.

For the purposes of describing and defining the present invention it is noted that the terms “battery”, “battery pack” or the like are utilized herein to represent a combination of individual battery cells used to provide electric current, preferably for vehicular, propulsive or related purposes. Furthermore, variations on the terms “automobile”, “automotive”, “vehicular” or the like are meant to be construed generically unless the context dictates otherwise. As such, reference to an automobile will be understood to cover cars, trucks, buses, motorcycles and other similar modes of transportation unless more particularly recited in context.

Having described the invention in detail and by reference to specific embodiments thereof, it will be apparent that modifications and variations are possible without departing from the scope of the invention defined in the appended claims. More specifically, although some aspects of the present invention are identified herein as preferred or particularly advantageous, it is contemplated that the present invention is not necessarily limited to these preferred aspects of the invention.

What is claimed is:

1. A method of forming an integrated voltage-sensing circuit for use in a battery-powered automobile propulsion system, said method comprising:
configuring said voltage-sensing circuit to comprise a fuse with leads for establishing electrical communication between a busbar and a terminal pin of at least one battery cell within said battery-powered automobile propulsion system;
forming a housing to rigidly secure said voltage-sensing circuit thereto; and
securing said housing to a frame that is configured to support said at least one battery cell such that said voltage-sensing circuit becomes an integral part of said frame.

2. The method of claim 1, wherein said fuse is mounted with a formation in said housing, said housing further comprising shaped formations therein to accept a connection from a corresponding portion of said busbar and said terminal pin.

3. The method of claim 2, wherein at least one of said fuse, said corresponding portion of said busbar and said corresponding portion of said terminal pin may be resiliently held within said housing.

4. The method of claim 3, wherein said forming a housing comprises molding said housing an electrically nonconductive material.

5. The method of claim 4, wherein said securing said housing to a frame comprises molding said frame around at least a portion of said housing.

6. The method of claim 5, wherein said molding said frame around at least a portion of said housing is performed such that said fuse is not encapsulated by said frame.

7. The method of claim 2, wherein said formation within said housing corresponding to said fuse defines a generally nonlinear path such that upon placement of said leads therein, said leads have a bend formed therein such that they exhibit enhanced strain relief relative to when said leads are substantially axially aligned.

8. The method of claim 1, further comprising electrically securing said fuse in said housing prior to said securing said housing to said frame.

9. The method of claim 1, wherein said busbar, said fuse and said terminal pin that define said integrated voltage-sensing circuit are configured as a modular whole within said housing such that together they define an autonomous part relative to said frame until such time as said housing is secured to said frame.

10. An assembly for sensing voltage produced by a battery cell within a battery pack made up of a plurality of said battery cells, said assembly comprising:
a frame configured to have said battery cell secured thereto;
a housing secured to said frame;
an electrically-conductive busbar;
an electrically-conductive terminal pin; and
a fuse disposed electrically between said busbar and said terminal pin such that said busbar, said fuse and said terminal pin define an integrated voltage-sensing circuit.

11. The assembly of claim 10, wherein said housing is integrally coupled to said frame.

12. The assembly of claim 11, wherein said frame is integrally molded around at least a portion of said frame.

13. The assembly of claim 12, wherein said integral mold formed around at least a portion of said frame is formed such that said fuse is not encapsulated by said frame.

14. The assembly of claim 13, wherein said fuse is secured to a separate housing that is secured to said frame.

15. The assembly of claim 10, wherein said integrated voltage-sensing circuit is configured as a modular whole within said housing such that together they define an autonomous part relative to said frame until such time as said housing is secured to said frame.

16. A battery pack configured to provide propulsive power to a vehicle, said battery pack comprising:
a plurality of battery cells;
a frame configured to have a respective one of said plurality of battery cell secured thereto; and
a voltage-sensing circuit secured to said frame; said voltage-sensing circuit comprising:
an electrically-conductive busbar;
an electrically-conductive terminal pin;
a fuse disposed electrically between said busbar and said terminal pin; and
a housing configured to maintain said fuse, said busbar and said terminal pin in electrical communication with one another.

17. The battery pack of claim 16, wherein said housing defines a molded structure such that said voltage-sensing circuit defines a modular unit.

18. The battery pack of claim 17, wherein said frame defines a molded structure.

19. The battery pack of claim 18, wherein said molded structure of said housing is further molded into said molded structure of frame to define an integral connection therebetween.

20. The battery pack of claim 16, wherein said housing defines a first formation therein for receiving said fuse said housing, a second formation therein to accept a connection from a corresponding portion of said busbar and a third formation therein to accept a connection from a corresponding portion of said terminal pin.
